(19) United States
(12) Patent Application Publication
(10) Pub. No.: US 2008/0079148 A1
(43) Pub. Date: Apr. 3, 2008

(54) PACKAGE FOR MIXED SIGNAL MCU WITH MINIMAL PIN COUNT

(75) Inventors: KA Y. LEUNG, AUSTIN, TX (US); JOHN M. CZARNOWSKI, AUSTIN, TX (US); DOUGLAS R. HOLBERG, WIMBERLY, TX (US); MATTHEW WEST, ALPHARETTA, GA (US); ROSS TODD BANNATYNE, AUSTIN, TX (US)

Correspondence Address: HOWISON & ARNOTT, L.L.P, P.O. BOX 741715, DALLAS, TX, 75374-1715, US

(73) Assignee: SILICON LABORATORIES INC., AUSTIN, TX (US)

(21) Appl. No.: 11/537,631

(22) Filed: Sep. 30, 2006

(51) Int. Cl. H01L 23/48

(52) U.S. Cl. 257/734

(57) ABSTRACT

A minimal pin package for a mixed signal integrated circuit for a mixed signal processor based integrated circuit includes a semiconductor chip having a plurality of bond pads disposed thereon with a digital processor digitally interfaceable with at least one of the bond pads. An analog circuit block is provided and interfaceable with at least one of the bond pads. A die pad is provided on which the chip is mounted and N terminals on the package are interfaced to the exterior of the package, one of which is integral with the die pad. Bond wires interface select ones of the bond pads to a supply designated one of the terminals, a ground one of the terminals and the die pad associated with one of the terminals, the rest of the N-3 terminals interfaced to remaining functionality of the chip.

### TECHNICAL FIELD OF THE INVENTION

The present invention pertains in general to package devices and, more particularly, to packaging associated with a microcontroller unit (MCU).

### CROSS-REFERENCE TO RELATED APPLICATIONS

None

### BACKGROUND OF THE INVENTION

As circuit boards become denser and the functionality of the chips increases, the trend toward manufacturing is to dispose a multi function chip with the potential of connecting to multiple output pins in a minimal pin package. Thus, even though multiple outputs could be connected to various input/output pins, it is possible to provide a functional package device that only utilizes certain functions of the chip. Of course, there is a minimal pin count beyond which the chip cannot function. There, of course, must be a power supply input and a ground input, in addition to some kind of data input/output. These data inputs/outputs will be a function of the application in which the chip will be disposed. Additionally, there are standard packages in which these chips will be disposed for use on various PC boards. Currently, packages available in 2 mm×2 mm square are in QFN packages where dimension of the package is near the chip-size dimension. This type of packages is widely used because of its smaller size, excellent thermal-electric performance and smaller lead inductance/capacitance. These are micro leadframe packages. These micro leadframe packages, at minimum, can have 8 pins. This means that two pins are used for the positive and negative voltages and this leaves 6 pins for all interface functions. This presents some difficulty when considering that these small packages can have microprocessors disposed therein. These microprocessors function with an on-chip bus with a width of 8 or 16 bits. Thus, the data input/output of this chip must somehow interface with these pins. This can typically be facilitated with a serial bus format. There are some formats that allow for a single wire communication and some that provide for a two wire serial bus communication, and even some providing four wires for serial bus communication.

### SUMMARY OF THE INVENTION

The present invention disclosed and claimed herein, in one aspect thereof, comprises a minimal pin package for a mixed signal integrated circuit for a mixed signal processor based integrated circuit. It includes a semiconductor chip having a plurality of bond pads associated or disposed thereon with a digital processor digitally interfaceable with at least one of said bond pads on the chip. An analog circuit block is provided and interfaceable with at least one of the bond pads on the chip. A die pad is provided on which the chip is mounted and N terminals on the package are interfaced to the exterior of the package, one of which is integral with the die pad. Bond wires interface select ones of the bond pads on the chip to a power supply designated one of the terminals, a ground one of the terminals and the die pad associated with one of the terminals, the rest of the N-3 terminals interfaced to remaining functionality of the chip.

### BRIEF DESCRIPTION OF THE DRAWINGS

For a more complete understanding of the present invention and the advantages thereof, reference is now made to the following description taken in conjunction with the accompanying Drawings in which:

FIG. 1a illustrates a diagrammatic view of one embodiment of the present invention showing a, minimal pin count;

FIG. 1b illustrates an alternate embodiment illustrating a second pin count;

FIG. 1c illustrates a third embodiment of the pin count for a package utilizing a nine pin package;

FIG. 2 illustrates a diagrammatic view of the MCU chip and the associated functionality that could potentially be connected to output pins;

FIG. 3 illustrates a second embodiment showing a diagrammatic view of a processor with various controls for the pin interfaces;

FIG. 4 illustrates a schematic diagram of the pin interface;

FIG. 5 illustrates a diagrammatic view of the data I/O;

FIG. 6 illustrates a perspective view of a QFN 9-pin package;

FIG. 7 illustrates a pop schematic view of the package and the bonding of the chip thereto;

FIG. 8 illustrates a cross-sectional view of a package of FIG. 7; and

FIG. 9 illustrates a cross-sectional view along the orthogonal axis to that of FIG. 8

FIG. 10 illustrates an alternate embodiment of FIG. 8;

FIG. 11 illustrates an alternate embodiment of FIG. 9; and

FIG. 12 is a bottom view of the package of FIG. 11.

### DETAILED DESCRIPTION OF THE INVENTION

Referring now to the drawings, wherein like reference numbers are used herein to designate like elements throughout the various views, embodiments of the present invention are illustrated and described, and other possible embodiments of the present invention are described. The figures are not necessarily drawn to scale, and in some instances the drawings have been exaggerated and/or simplified in places for illustrative purposes only. One of ordinary skill in the art will appreciate the many possible applications and variations of the present invention based on the following examples of possible embodiments of the present invention.

It will be appreciated by those skilled in the art having the benefit of this disclosure that this invention provides a low cost MCU device with a minimal pin count package, where the package cost is a smaller fraction of the total cost. It should be understood that the drawings and detailed description herein are to be regarded in an illustrative rather than a restrictive manner, and are not intended to limit the invention to the particular forms and examples disclosed. On the contrary, the invention includes any further modifications, changes, rearrangements, substitutions, alternatives, design choices, and embodiments apparent to those of ordinary skill in the art, without departing from the spirit and scope of this invention, as defined by the following claims. Thus, it is intended that the following claims be interpreted to embrace all such further modifications, changes, rearrangements, substitutions, alternatives, design choices, and embodiments.

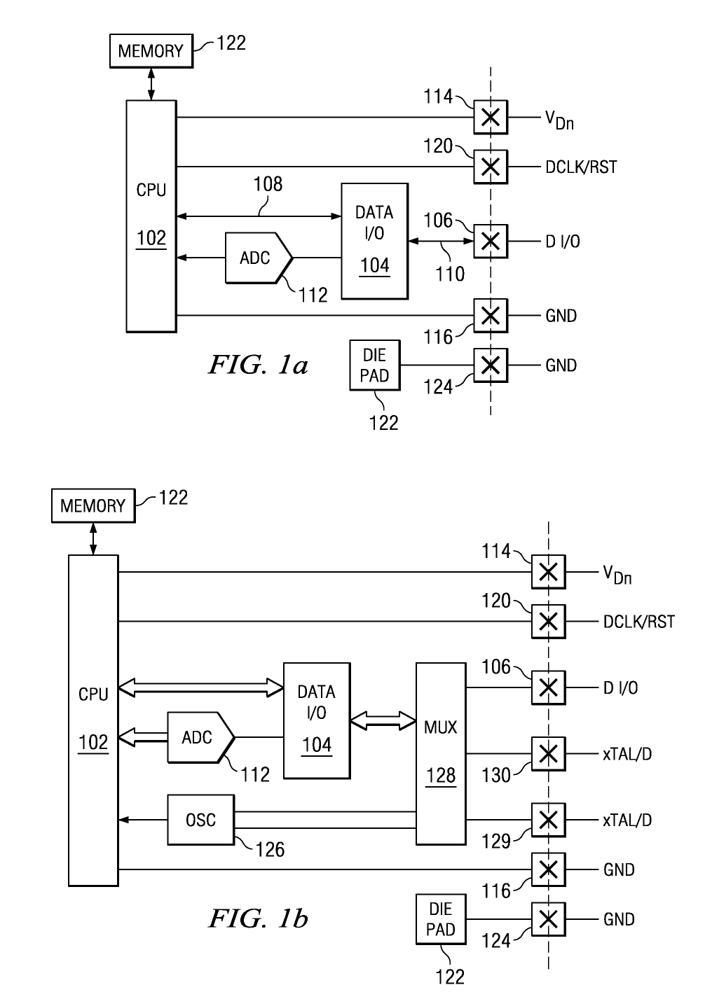

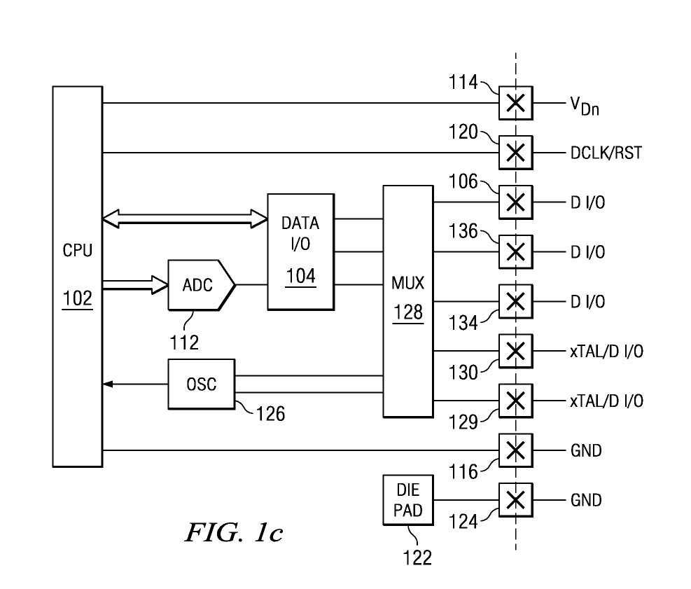

Referring now to FIG. 1a, there is illustrated one embodiment of the invention. This invention utilizes at the heart thereof a microcontroller unit (MCU) that is comprised of, at the processing core thereof, a CPU 102. This CPU, in the current embodiment, is based on the 8051 architecture. This is an area of conventional architecture. Although not all of the elements associated with the MCU are illustrated in FIG. 1a, there is illustrated a data input/output (I/O) 104 that is disposed between the CPU and a single data I/O pin 106. Data is transmitted to and from the data I/O 104 from the CPU 102 over a bus 108 and transmitted between the pin 106 and the data I/O 104 over a bus 110. Additionally, the data I/O 104 can receive analog input signals such as audio input signals for input to analog-to-digital converter (ADC) 112. Thus, the data I/O port 106 can be associated either with digital inputs, digital outputs or analog inputs, depending upon the configuration of the system.

In addition to the data I/O 106, there is also provided a power supply pin 114 and a chip ground pin 116. These are connected to the respective positive and negative power supply inputs of the chip and associated with the operation of the CPU 102 and the other peripheral circuitry associated therewith. There is also required for the operation of the MCU a reset pin 120 that is operable to receive a reset input and also a data clock. There are a minimal number of pins provided for the system and, as will be described herein below, the CPU has associated therewith memory in the form of flash memory in a block 122. This provides configuration information for the operation of the MCU. Thus, there must be a way to input data to the memory and this is facilitated with the data input pin 106 which, in a power up mode, can be configured to receive data. When data is received, a data clock is required and this is provided on the pin 120. After data is input and certain information is transmitted thereto, the configuration can then be altered to reconfigure the data I/O pin 106 for receiving or transmitting digital data or receiving analog data.

Since this device utilizes both digital and analog signals, it is referred to as a mixed signal device. As such, there is a possibility for noise interference. To reduce noise, the actual die upon which the integrated circuit comprising the CPU 102, data I/O 104, ADC 112 and memory 122 is connected to a die pad 123, which is connected to a second ground pin 124. This is a separate pin from the pin 116. Thus, there are provided two ground pins, one for the chip ground and one for the die pad ground.

In operation, this chip operates with a minimum pin count of 5 pins. At the minimum, there must be a supply pin, pin 114, and two ground pins, ground pin 116 and ground pin 124. In addition, to be of any functional use, there must be at least a single data I/O pin, pin 106. This is for the purpose of receiving digital data, transmitting digital data or a multiplexed operation thereof and possibly receiving analog data. This, of course, depends upon the configuration of the system, which configuration is typically stored in the memory 122. Additionally, there must be some way to program the memory 122. The memory 122, as will be described herein below, is a non-volatile programmable memory of Flash type. Upon power up of the part, there will be a mode that allows data to be input thereto. This could also occur upon reset operation. In this data input mode, the pin 106 is configured to the data input pin for serial clocked data. The clock 120 clocks this data into the data I/O 104 in a synchronous manner. The system is configured such that this data is stored in memory 122. During this clocking of data, a command can be sent that will indicated the end of the data input mode and this will then configure the chip in the particular functionality associated therewith.

Referring now to FIG. 1b, there is illustrated an alternate embodiment form the chip of FIG. 1a with additional pins illustrated. In this embodiment, there is provided an oscillator 126 for allowing operation of the CPU 102 and the other functions thereon, i.e., this provides the base clock. In the embodiment in FIG. 1a, although an oscillator was not illustrated, there is an oscillator contained on chip, but this is not a crystal controlled oscillator. In the embodiment of FIG. 1b, the oscillator 126 is a crystal controlled oscillator which requires an external crystal. A multiplexer 128 is provided for multiplexing the operation of the data I/O pin 106 with two additional pins 129 and 130 provided for. These two pins are input to the multiplexer 128 and can function in one mode as crystals wherein a crystal oscillator is required or, in a second mode, as two additional data pins. The multiplexer 128 is operable to configure these three pins to be either data or data and crystal. As such, the data I/O block 104 can provide a data interface to the multiplexer 128 to allow digital data to be input/output or to receive analog data. Any of the data functionalities can be associated with the pins 106, 129 and 130, respectively by the multiplexer 128 or, alternatively, the pins 129 and 130 could be configured for use with a crystal in association with the oscillator 126. This configuration, the minimal number of pins would be 7 pins.

Referring now to FIG. 1c, there is illustrated an alternate embodiment depicting a 9 pin device. In this embodiment, there are provided two additional data I/O pins 134 and 136.

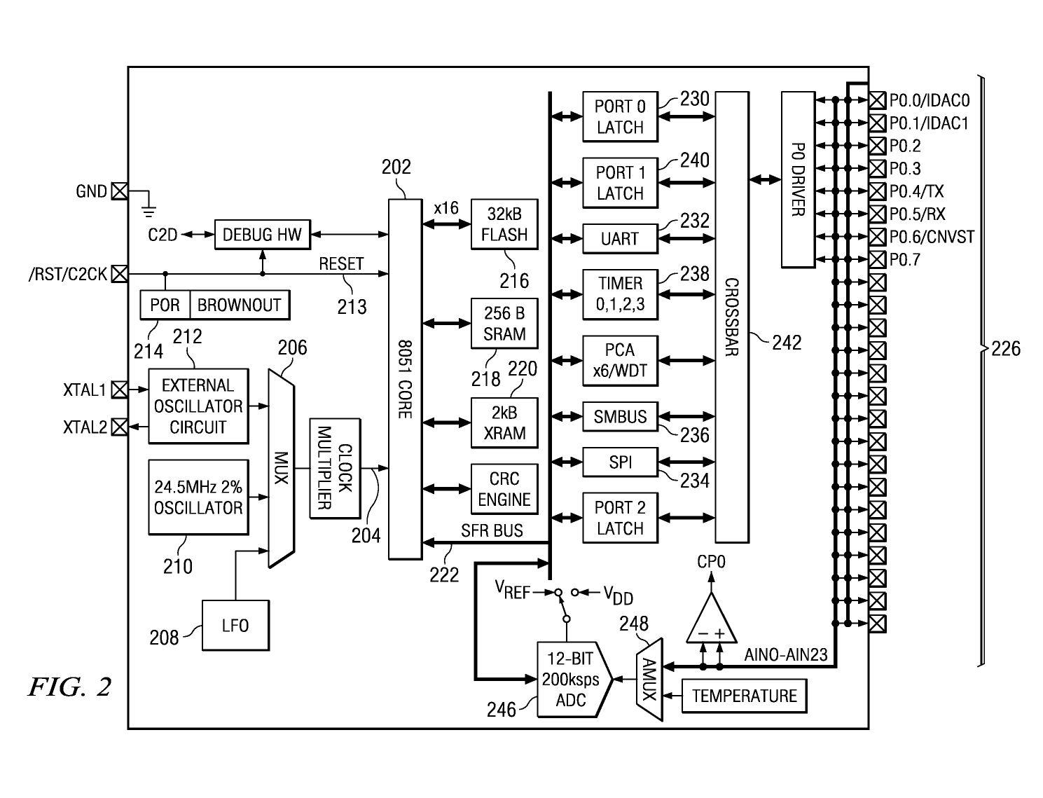

Referring now to FIG. 2, there is illustrated a block diagram of the MCU. As noted herein above, the MCU is generally of the type similar to part number C8051F330/1 manufactured by Silicon Laboratories Inc. The MCU includes in the center thereof a processing core 202 which is typically comprised of a conventional microprocessor of the type “8051.” The processing core 202 receives a clock signal on a line 204 from a multiplexer 206. The multiplexer 206 is operable to select among multiple clocks. There is provided an 80 kHz internal oscillator 208, a 24.5 MHz trimmable internal precision oscillator 210 or an external crystal controlled oscillator 212. The precision internal oscillator 210 is described in U.S. patent application Ser. No. 10/244,344, entitled “PRECISION OSCILLATOR FOR AN ASYNCHRONOUS TRANSMISSION SYSTEM,” filed Sep. 16, 2002, which is incorporated herein by reference. The processing core 202 is also operable to receive an external reset on terminal 213 or is operable to receive the reset signal from a power-on-reset block 214, all of which provide a reset to processing core 202. The processing core 202 has associated therewith a plurality of memory resources, those being either flash memory 216, SRAM memory 218 or random access memory 220. The processing core 202 interfaces with various digital circuitry through an on-board digital bus 222 which allows the processing core 202 to interface with various operating pins 226 that can interface external to the chip to receive digital values, output digital values, receive analog values or output analog values. Various digital I/O circuitry are provided, these being latch circuitry 230, serial port interface circuitry, such as a UART 232, an SPI circuit 234 or an SMBus interface circuit 236. Three timers 238 are provided in addition to another latch circuit 240. All of this circuitry 230-240 is interfacable to the output pins 226 through a crossbar device 242, which is operable to configurably interface these devices with select ones of the outputs. The digital input/outputs can also be interfaced to to the digital output of an analog-to-digital converter 246 that receives analog input signals from an analog multiplexer 248 interfaced to a plurality of the input pins on the integrated circuit. The analog multiplexer 248 allows for multiple outputs to be sensed through the pins 226 such that the ADC can be interfaced to various sensors. Again, the CPU/MCU is a conventional circuit.

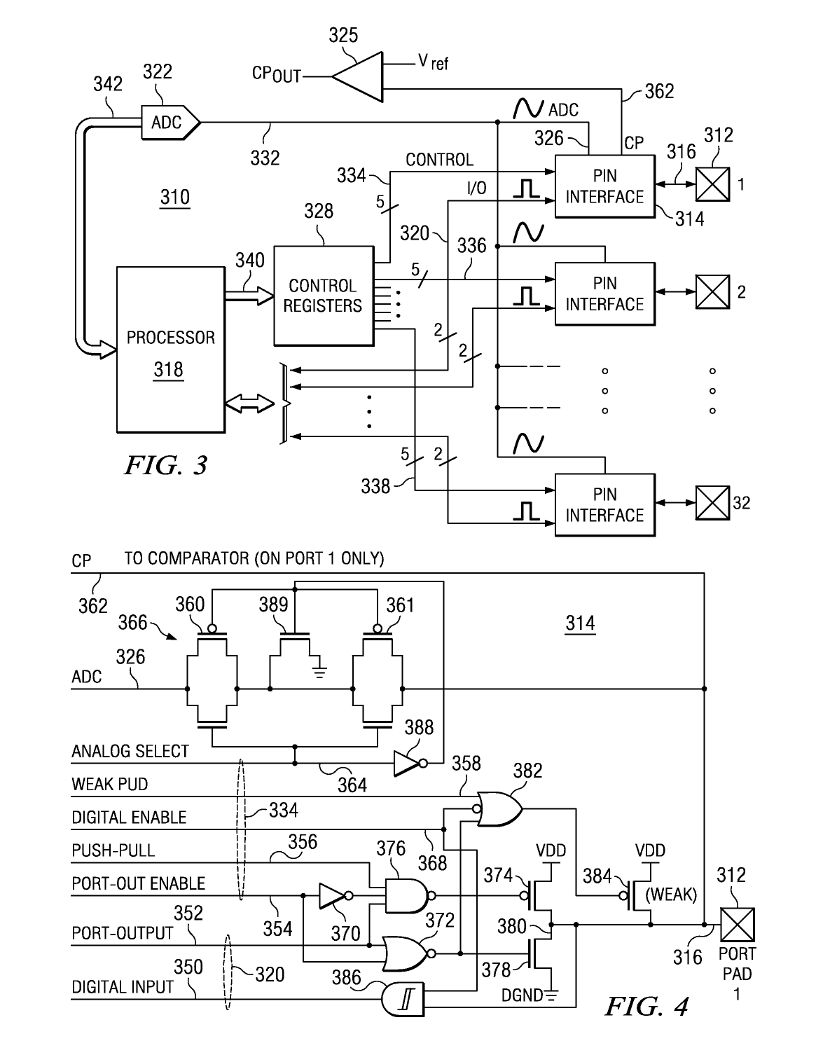

With reference now to FIG. 3, there is illustrated the various analog and digital circuits involved in the described embodiment that utilize many of the analog/digital pin interface circuits and corresponding contact pads of the integrated circuit. The integrated circuit includes a number of contact pads or connection pins, designated numerically from one to thirty-two. Although only thirty-two I/O pins are illustrated, the invention can be adapted to any circuit irrespective of the number of I/O pins. Each pin, for example, Pin 1 is coupled to a pin interface 314. The pin interface 314 couples analog or digital signals to or from the I/O contact pad 312 on conductor 316. The pin interface 314 can couple digital signals to digital circuits, such as a processor 318 on one conductor of a two-wire path 320, or receive digital signals therefrom on the other conductor of the two-wire path 320. The pin interface 314 can also couple analog signals to analog circuits, such as an analog-to-digital converter 322, by way of a common analog line 332. Those skilled in the art may also find it advantageous to couple the common analog line 332 to other types of analog processing circuits, such as analog wave shaping circuits, comparators, amplifiers, etc. The externally-generated analog signals received from the pin interface 314 are coupled via a transmission gate in the pin interface on analog line 326. The analog signals coupled to the pin interface 314 can also be coupled on line 362 to a comparator 325 for comparison with either a fixed or programmable reference voltage. Other analog monitor circuits can also be utilized.

The analog transmission gate in each pin interface circuit is controlled by a respective control line connected to a control register circuit 328. The analog output of each such analog transmission gate is wire-OR'd together to form the common analog line 332. The overall function of the transmission gates in the respective pin interface is to provide a 32:1 multiplexer. The processor 318 controls the logic states of the registers in the circuit 328 to select which one of the thirty two analog transmission gates will be active to couple the associated analog signal to the ADC 322. While FIG. 3 illustrates in principle the distributed nature of the analog transmission gate multiplexer, other unified multiplexers could be utilized. In addition, those skilled in the art may prefer to employ different multiplexer arrangements, such as 32:2 type multiplexers, and others.

Each of the other pin interface circuits are interconnected and operate in the same manner for coupling digital signals between the respective contact pads and the processor 318, or for coupling analog signals between the contact pads and the ADC 322 and/or comparator 325. Each pin interface circuit is controlled as to whether the operation thereof will be digital or analog, using control signals output by control registers 328. The control registers 328 provide a number of outputs for controlling distributed analog multiplexing circuits in the pin interfaces. In the example, since there are thirty-two pin interface circuits with corresponding contact pads, the control register circuit 328 provides thirty-two separate control signals for individually controlling the multiplexing circuits in each pin interface. The control register circuit 328 also provides other control signals for controlling the pin interfaces. For example, on the five control register outputs 334, the various circuits of the first pin interface 314 are controlled. Control register outputs 336 control the circuits in the second pin interface, and so on in a similar manner. Lastly, the pin interface associated with pin 332 is controlled by signals on control register lines 338.

The various circuits of the integrated circuit 310 shown in FIG. 3 operate in the following manner. When it is desired to configure a pin interface for receiving digital signals and driving the same on the respective contact pads, the following operations are carried out. The processor 318 is programmed to configure the pin interfaces in various modes. When it is desired to configure the pins for driving digital signals, control signals are generated by the processor 18 and coupled on bus 340 to the control registers 328. The control registers 328 latch the control signals therein and provide steady state control signals to the various pin interface circuits to be controlled. In order to configure the first pin interface 314 for driving digital signals, a control signal is placed on one conductor of control line 334 to configure the first pin interface 314 into a mode for driving digital signals to the I/O contact pad 312. The processor 318, then transmits digital signals on one line of the 2-wire bus 320 directed to the first pin interface 314. The pin interface 314 then drives such digital signals on conductor 316 to the I/O contact pad 312.

When it is desired to configure the pin interface 314 in a mode for receiving externally-generated digital signals from the I/O contact pad 312, appropriate control signals are generated by the processor 18 and transferred to the control registers 328 on bus 340. The control signals on line 334 will be maintained for the digital operating mode, but the processor 318 will reconfigure itself so as to receive digital signals from the pin interface 314 on the other conductor of the 2-wire bus 320. In this manner, digital signals are coupled externally to the I/O contact pad 312, and therefrom to the processor 318 via the pin interface 314. The remaining pin interface circuits function in the same manner.

When it is desired to configure the pin interfaces, such as the first pin interface 314 for operating in an analog mode, the processor 318 writes the appropriate control registers 328 to provide different control signals on the control lines 334. When configured for analog operation, the pin interface 314 receives externally-generated analog signals from the I/O contact pad 312 and couples the same via an internal transmission gate on analog line 326 to the common analog line 332. When configured for analog operation, the control registers 328 are also written to produce appropriate logic states on the bus 334, whereupon the internal analog transmission gate is enabled. The analog line 326 is thus selected for coupling the analog signals thereon through the transmission gate to the common analog output line 332. Analog signals can thus be coupled from the I/O contact pad 312 through the pin interface 314 to the analog-to-digital converter 322. When the ADC 322 converts the analog signals to corresponding digital signals, such digital signals can be coupled on the bus 342 to many other digital circuits, including the processor 318. The digital signals on bus 342 can then be processed by the processor 318 and the result thereof transmitted back to the pin interfaces during a digital mode of operation.

As noted above, the analog signals can also be coupled from the pin interface 314 to the comparator 325 for comparison with a predefined or programmable reference voltage. If all the analog lines of each pin interface are to be used for comparison with a reference voltage, the common analog line 332 can be connected to the input of the comparator 325.

While the pin interface 314 is illustrated in FIG. 3 as being configured so as to provide for the input of analog signals, the output of analog signals can also be achieved. In providing a bi-directional flow of analog signals with regard to the pin interface 314, the pin interface transmission gate can be controlled to allow externally-generated analog signals to not only be input to the pin interface 314, but also allow internally-generated analog signals to be output therefrom as well. With this alternate arrangement, on-board analog signal generating circuits can be coupled through an analog selector or multiplexing arrangement to the common analog bus 3032, for transferring the analog signals to the various pin interfaces.

Reference is now made to FIG. 4 where there is shown in functional detail only one pin interface circuit 314. The other pin interface circuits are constructed and operate in an identical manner. While the various logic functions carried out by the pin interface circuit are shown as implemented by traditional logic gates, in practice such functions are carried out by various types of transistor circuits which perform the logic functions. Those skilled in the art can readily devise many different types of transistor circuits to carry out the noted logic functions. Many of the signals coupled to the pin interface circuit 14 are generated by the microprocessor 318. In the preferred embodiment, a triplet of the signals is coupled to each pin interface circuit by way of a priority cross-bar decoder. The cross-bar decoder circuit is described in detail in pending applications of the assignee identified as U.S. application Ser. No. 09/584,308 filed May 31, 2000 and application Ser. No. 09/583,260 filed May 31, 2000, the subject matter of such applications being incorporated herein by reference. In view that a cross-bar decoder is not essential to the operation of the present invention, such circuit will not be described here. Rather, it is sufficient to understand that the pin interface circuit 314 of the invention need only be coupled either directly or indirectly to analog and digital circuits, and controlled accordingly by suitable control circuits.

The relevant signals shown in connection with the pin interface circuit 314 of FIG. 4 function in the following manner. The Digital Input signals carried on line 350 constitute the digital signals coupled from the I/O contact pad 312 to the digital circuits 318 of the integrated circuit 310. The signals carried on the Port-Output line 352 are the digital signals coupled from the digital circuits 318 of the integrated circuit 310 to the I/O contact pad 312. Lines 350 and 352 constitute the two-wire bus conductor 320 shown in FIG. 3. The Port-Out enable line 54 carries the control signals generated by the processor 318, or support circuits therefor, for enabling and disabling operation of the pin interface circuit 314. In particular, when the Port-Out enable signal on line 54 is driven by the multiprocessor 318 to a logic low state, the pin interface circuit 314 is operative to allow digital signals to be output to the I/O contact pad 312. When at a logic high state, the Port-Out enable line 354 causes the conductor 316 coupling the pin interface circuit 314 to the contact pad 312, to be driven to a high impedance state. The Push-Pull line 356 carries signals which allow a push-pull driver of the pin interface circuit 314 to be operational. The Weak Pud signal on line 358 controls the operation of a weak pull-up transistor coupled to the conductor 316. The ADC signal on line 326 is the analog signal carried from the I/O contact pad 312 to the common analog line 332 of FIG. 3. Control lines 354, 356, 358, 364, and 368 of FIG. 4 constitute the five-wire bus conductor 334 shown in FIG. 3.

The CP signal on line 362 can be coupled to the comparator 325 shown in FIG. 3. The processor 318 can cause digital or analog signals carried on the conductor 316 to be coupled to the comparator 325 for comparison with a reference voltage that is programmable to different amplitudes. While only pin interface circuit 314 is shown equipped with the capability of being coupled to the comparator 325, one or more of the other pin interface circuits can be designed to provide a similar function.

The Analog Select signal on control line 364 controls an analog transmission gate circuit 366 to allow the coupling of externally-generated analog signals input to the I/O contact pad 312 to analog signal processing circuits. In practice, the analog transmission gate circuit 366 is a pair of series-connected analog transmission gates 360 and 361, which if enabled, allows analog signals to pass therethrough in either direction. Each transmission gate 360 and 361 each constitutes a P-channel and N-channel transistor. The Analog Select control signal on line 364 drives the N-channel transistors, and such control signal drives the P-channel transistors by way of an inverter 388. If the transmission gate 366 is not enabled, the connection between the individual transmission gates is pulled to a ground potential by transistor 389, thereby isolating the unused terminals which may otherwise have digital signals, noise, cross-talk or other signals imposed thereon. This is an important feature of the pin interface 314 because it enables the multiplexer to select or to isolate the analog signal at the I/O contact pad 312 or pin location. Otherwise, thirty-two analog signals would have to be routed to a multiplexer cell located external to the pin interfaces. With this invention, only one analog route, (or fewer than thirty-two routes depending on the manner in which external multiplexers 324 are configured, see FIG. 3), is connected to all of the pin interfaces being multiplexed onto the common analog line 332. This enables the pin interfaces to be distributed more ubiquitously about the perimeter or area of the semiconductor chip (or PCB).

The Digital Enable signal on control line 368 disables the weak pull-up transistor 384 and the logic gate 386 during analog operation. Automatic disabling of the weak pull-up transistor 384 is optional.

In the operation of the pin interface circuit 314 of FIG. 4, a logic high state of the Port-Out enable signal on line 354 is coupled through an inverter 370 to present a logic low state on an input of NAND gate 376. The output of the NAND gate 376 is a logic high which drives a P-channel transistor 374 of a push-pull driver, thereby turning it off. The Port-Out enable signal on line 354 also drives an input of a NOR gate 372 in the pin interface circuit 314. The output of the NOR gate 372 drives an N-channel driver transistor 378 of the push-pull driver to a low level, thereby turning it off. As a result, push-pull output 380 of the driver transistors 374 and 378 is placed in a high impedance state, which state is coupled to the corresponding I/O contact pad 312 via conductor 316. Thus, when the Port-Out enable signal is at a logic high state, the I/O contact pad 312 is driven to a high impedance state. This feature can be advantageously used when it is desired to place an I/O pin of the integrated circuit 310 in an input mode. The tristate condition of the driver can also be used when the signals of the integrated circuit 310 are “settling” to a stable state. This prevents temporary-state transitions and glitches from appearing at the I/O contact pad. Also, when the Port-Out enable signal is high during this transition period, no erroneous signals will appear at the I/O contact pad 312. Those skilled in the art may also utilize additional circuits connected to the P-channel driver transistor 374 and the N-channel driver transistor 378 to prevent both such transistors from being driven into conduction at the same time. Moreover, those skilled in the art may find that not all pin interface circuits should be driven into a high impedance state at the same time. To that end, different control lines in lieu of line 354 can be coupled to the pin interfaces.

With reference again to the I/O pin interface circuit 314, it is noted that if the driver is configured to an operational state in which the logic state on line 354 is at a low state, the I/O contact pad 312 can be driven to the logic state corresponding to the data on the Port-Output line 352. As noted in FIG. 4, the Port-Output signal on line 352 is coupled to an input of the NOR gate 372, as well as to an input of the NAND gate 376. For purposes of example, it is assumed that the driver transistors 374 and 378 are to be operated in a push-pull manner. Accordingly, the Push-Pull control line 356 is driven by the microprocessor 318 to a logic high level. Assuming further that the logic state on the Port-Output line 352 is driven to a logic high, then the output of the NOR gate 372 will be logic low, thereby turning off the N-channel driver transistor 378. On the other hand, the output of the NAND gate 376 will be at a logic low level, thereby driving the P-channel driver transistor 374 into conduction. The I/O contact pad 312 will thus be driven to a logic high state, corresponding to the logic high state on the Port-Output line 352. Digital data can thus be coupled from the Port-Output line 52 to the I/O contact pad 312.

If, on the other hand, the logic state of the digital data on the Port-Output line 352 is at a logic low state, then the output of the NOR gate 372 will be logic high state. The output of the NAND gate 376 will be at a logic high state also. The P-channel driver transistor 374 will thus be turned off, while the N-channel driver transistor 378 of the push-pull pair will be driven into conduction. The logic state of the I/O contact pad 312 is thus a logic low, corresponding to the logic low state on the Port-Output line 352.

In the event that the I/O contact pad 312 is to be provided with a weak pull-up, then the control line 358 is driven to a logic low state. If the output of the NOR gate 372 is also at a logic low state, the OR gate 382 will bias the P-channel driver transistor 384 into conduction. The weak pull-up transistor 384 is constructed with a long conduction channel, thereby providing a high resistance between the supply voltage VDD and the I/O contact pad 12. A weak pull-up to the I/O contact pad 312 is thus provided. A separate weak pull-up control line is coupled to each of the pin interface circuits, and such lines are controlled by way of the control registers 328. In like manner, each pin interface circuit is controlled by a separate Push-Pull control signal line, one shown as reference number 356. The push-pull control lines are also controlled by the control registers 328.

In order to configure the I/O contact pad 312 for the input of digital signals, the Port-Out enable signal on line 354 is driven to a logic high state. As noted above, both push-pull transistors 374 and 378 are turned off, thereby placing the I/O contact pad 312 in a high impedance state. Accordingly, external analog and digital signals can be applied to the I/O contact pad 312. The input digital signals on I/O contact pad 312 are coupled via the conductor 316 to an input of AND gate 386, and therethrough to Digital Input line 350. With reference to FIG. 3, the input data signals on line 350 of bus 320 can be coupled to the microprocessor 318 or other digital circuits.

As noted above, when the I/O contact pad 312 is utilized for the input or output of digital signals, the Digital Enable signal on control line 368 is driven to a logic high level. The logic high input to the two-input AND gate 386 allows digital signals to be passed from the I/O contact pad 312 to the microprocessor 318. Also, the logic high state of the Digital Enable signal places an enabling signal on the inverting input of the OR gate 382, thereby enabling operation of the Weak Pull-up transistor 384, if the Weak PUD signal on line 358 is asserted. As can be appreciated, the foregoing represents an OR function in controlling the weak pull-up transistor 384.

When it is desired to configure the I/O contact pad 312 for receiving analog signals, the Port-Out enable control signal on line 354 is driven to a logic high state, thereby placing the push-pull transistors 374 and 378 in a high impedance state. Additionally, the Digital Enable signal on control line 368 is driven to a logic low. This disables the weak pull-up transistor 384 via the OR gate 382, and disables the AND gate 386. It is important to disable the logic gates having inputs coupled to the I/O contact pad conductor 316, otherwise the analog voltages may not only drive the logic gates to different states, but may also activate push-pull transistors in such gates so that current flows therethrough. In other words, analog voltage levels may be encountered on the I/O contact pad 312 that will not drive the logic gates to either a logic high or low state, but rather drive such gates to an indeterminate logic state. Such indeterminate logic states can often cause unnecessary current flow therein, which is wasteful of power in the integrated circuit. Various types of logic gates may include additional protection circuits to prevent large current flow therethrough when driven by a signal with an indeterminate logic state. When utilizing such type of logic circuits, the AND gate 386 may not be required to be disabled during analog operation.

In any event, when the pin interface circuit 314 is configured for analog operation, the Analog Select signal on control line 364 is driven to a logic high state, thereby allowing signals to be passed through the analog transmission gate circuit 366. As noted above, each pin interface circuit includes a transmission gate circuit which is part of a distributed multiplexer. Analog signals can thus pass unimpeded from the I/O contact pad 312 to the analog-to-digital converter 322. When it is desired to convert the analog signals coupled to I/O contact pad 312 to corresponding digital signals, the appropriate control signals are generated by the microprocessor 318, are latched in the control register 328, and are coupled to the pin interface circuits. In the embodiment shown in FIGS. 3 and 4, only one pin interface circuit is enabled for analog operation at a time. The pin interface circuit enabled for analog operation will couple the analog signals coupled thereto to the common analog line 32 via the analog transmission gate circuit in the enabled pin interface circuit. In the other pin interface circuits disabled for analog operation, the isolated transistor 89 in the respective analog transmission gate circuits will be driven into conduction, thereby providing electrical isolation between the common analog line 32 and the circuits of the disabled pin interface circuits. The microprocessor 18 can also control the ADC circuit 22 to commence conversion of the analog signal to a corresponding digital word.

As noted in FIGS. 3 and 4, the input of the comparator 325 is also coupled to the I/O contact pad 312 connected to the pin interface 314. Either analog signal levels or digital signal levels can be compared with a reference voltage to verify acceptable circuit operation. Indeed, the microprocessor 318 can drive the I/O contact pad 312 with a logic level, and verify with the comparator 325 that such level is within specified limits. The comparison operation can be carried out by increasing (or decreasing) the variable reference voltage until the output of the comparator changes state. The voltage magnitude of the signal on the I/O contact pad 312 can thus be determined.

As an alternative, a signal coupled to the I/O contact pad 312, whether it be a digital input/output or analog signal, may be routed through the respective analog transmission gate circuit 366 as previously described, and measured directly by the ADC 322 using N bits of resolution. This feature of the present invention adds to the capabilities of the commonly known SCAN testing method. With SCAN chain testing, there is provided the ability to test the digital I/O signals coupled to the integrated circuit. This invention in one of its embodiments may be extended to add analog level sensitivity testing to the scan chain by using the comparator 325 or ADC 322 as described above, to measure the signal amplitude on the I/O contact pad 312 and provide a pass or fail condition as appropriately determined by the scan chain.

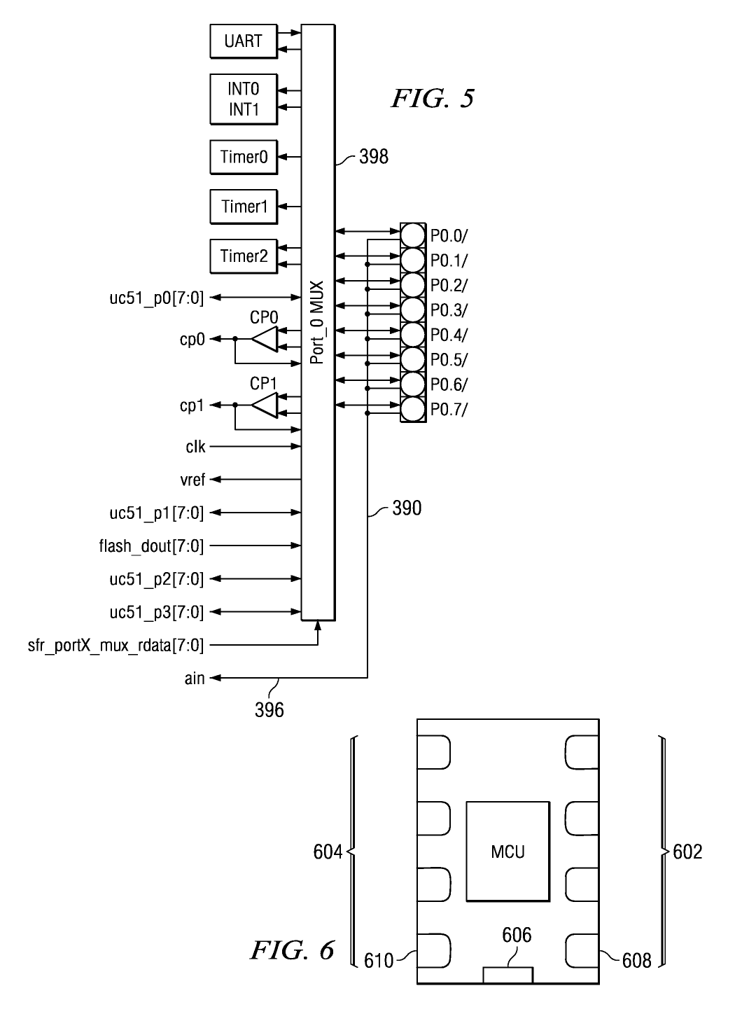

With reference now to FIG. 5, there is illustrated a preferred embodiment of the invention, showing the manner in which the digital and analog lines of each pin interface are connected to the respective support circuits. Shown are four ports, each having eight I/O contact pads, totaling thirty-two I/O contact pads for the integrated circuit 310. The designation, for example P1.6/SYSCLK, identifies port 1 of the four ports, and pin 6 of that port. The pneumonic identifier indicates that the system clock signal can be multiplexed onto the port pin. In contrast with the embodiment shown in FIG. 3, where each analog conductor of the thirty two pin interface circuits is connected to a common analog line 332, single multiplexer 324, the multiplexing arrangement shown in FIG. 5 is different. In the FIG. 5 embodiment, the analog lines of each port interface driver in a group are connected together to provide a common analog line for the group. In other words, each of the eight pin interface circuits of port 300 are coupled together, and extended by a common analog line 390 to one input of a four-input multiplexer 392. The eight analog lines of port 1 are similarly connected together, and extended as a second common analog line 394 to a second input of the multiplexer 392. The analog lines of the port 2 and port 3 groups of pin interfaces are similarly connected and coupled as respective third and fourth common analog lines to the remaining two inputs of the multiplexer 392. The multiplexer 392 requires only two digital signals for decoding in order to select one of the four analog inputs for coupling signals on the selected common analog line to the output 396 of the multiplexer 392. With this arrangement, fewer conductors are required to be extended between the port interface driver circuits and the multiplexer 392. While not specifically shown, each group of port interface driver circuits requires an analog select decoder for decoding a 3-bit digital word to select one of the analog select signals 364 of each group. With this arrangement, even if multiple port I/O contact pads are driven by analog signals, the operation of only one analog transmission gate circuit 366 (FIG. 3) ensures that only single analog signal is coupled from that group on the common analog line to the multiplexer 392. As can be appreciated, even though a multiplexer 392 external to the port interface driver circuits is utilize, the distributed multiplexer employing the analog transmission gate circuits 366 is nevertheless used in each pin interface circuit.

As further shown in FIG. 5, there are additional multiplexers 398-404 for multiplexing the digital signals with regard to the various pin interface groups, and port I/O contact pads.

Various other analog line multiplexing schemes can be utilized. For example, the first analog line of each port can be connected in common to one input of an eight-input multiplexer. The second analog lines of each port can similarly be connected together and coupled to a second input of the multiplexer. The other six analog lines of the four ports can be similarly connected to the multiplexer. With eight multiplexer inputs, a 3-bit word can be used to select which one of the eight analog lines is to be coupled to the ADC, or to other analog processing circuits, such as comparators, amplifiers, wave shaping circuits, etc.

From the foregoing, disclosed is a pin interface circuit adapted for carrying both analog and digital signals. The pin interface circuit can be configured to carry digital signals through the pin interface circuit to the port I/O contact pad in one direction, or in the other direction. In addition, the pin interface circuit can be configured to disable the digital circuits so that analog signals can be carried therethrough without affecting the digital circuits.

While the preferred and other embodiments of the invention have been disclosed with reference to a specific pin interface circuit, and method of operation thereof, it is to be understood that many changes in detail may be made as a matter of engineering choices, without departing from the spirit and scope of the invention, as defined by the appended claims.

Referring now to FIG. 6, there is illustrated a diagrammatic view of a standard QFN package with 9 pins. There are provided a group of 4 pins 602 on one side and 4 pins 604 on the opposite side on one surface. There is additionally provided at one end a 9^{th} pin 606. One of the pins, a pin 608, of the group 602 is associated with ground and one of the pins, a pin 610, of group 604, is associated with VDD. The pin 606 is the die pad ground. These are standard packages and with sizes ranging from less than 1 mm×1 mm to greater than 12 mm×12 mm.

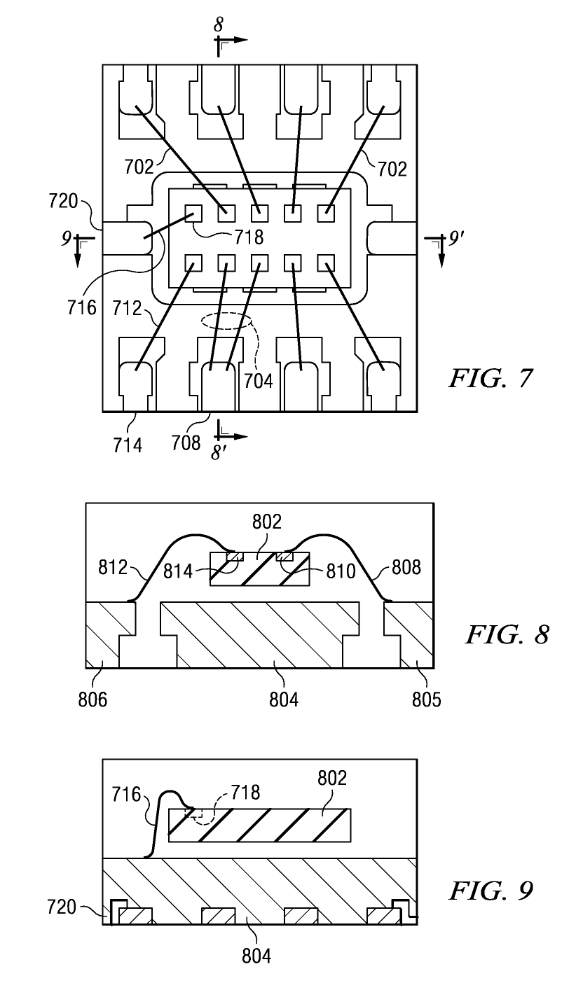

Referring now to FIG. 7, there is illustrated a schematic view of the package at one end illustrating the bond out for a chip requiring VDD, ground and 6 functional pins on the chip itself. It could be seen that each of the pins is associated therewith a bond wire 702 from the surface of the chip. In this configuration, there are provided 10 bond pads on the chip. Of these, there are provided two bond wires 704 connected to a single pad 708. There is provided a single ground bond wire 712 that is connected to the ground lead 714. Additionally, there is a second bonding pad 716 on the chip that is connected with a bond wire 718 to a 9^{th} terminal 720. Thus, it can be seen that of the 8 terminals on the side, 9 bond pads on the chips are associated therewith. The additional bond pad 716 on the chip is connected to the die pad, that is connected to the 9^{th} terminal. The 9^{th} terminal is illustrated as being interfaced with both ends of the package, it being understood that this is a single terminal, as it has a single connection. As noted above with respect to FIG. 1a, the number of actual functional outputs from the packaged chip could be as low as 5 and this would still provide a fully functional mixed signal integrated circuit with a processor based core. Further, this is a configurable processor core that has a non-volatile memory associated therewith that can be programmed such that program information can be downloaded to the processor core for storing configuration information therein, which configuration information can then be utilized to control the operation thereof.

Referring now to FIG. 8, there is illustrated a cross sectional view of the package of FIG. 7 taken along the lines 8-8′. The chip is provided by a die 802 that is disposed on a die pad 804, this being what the 9^{th} terminal is connected to. There is illustrated a terminal 805 on the right side of the chip and a terminal 806 on the left side. A bond wire 808 is connected from a pad 810 on the die 802 and then to the terminal 805. Similarly, a bond wire 812 is connected between bonding pad 814 on the die 802 and then to the terminal 806.

Referring now to FIG. 9, there is illustrated a cross sectional diagram of the package of FIG. 7 taken along line 9-9 prime. The die pad 804 is illustrated in cross section, which extends over to the terminal 720. The bond wire 716 connects the bonding pad 718 on the die 802 to the terminal 720. It can be seen that by connecting the bond wire 716 directly to the terminal 720, this bond passes any resistance that may exist between the bottom surface of the die 802 and the die pad 804. The die 802, during manufacturing, typically has a thin layer of oxide on the bottom surface thereof. In order to insure proper grounding of the substrate, sometimes the bottom surface of the die is polished, this done to fit the die into the package, typically. The bond wire 716 is utilized to the die pad and this is typically referred to as a “down bond.” For mixed signal devices, this additional terminal is required, even though it adds an additional terminal to the package. Further, the down bond 716 is utilized to a terminal that connects external to the package, as opposed to connecting it to the die pad and then connecting the die pad up to the terminal 714 associated with the chip ground. The reason for this is that the additional inductance required for bonding down to the die pad and then back up to the terminal can add noise to a mixed signal integrated circuit comprised of a digital processor and an analog data conversion section.

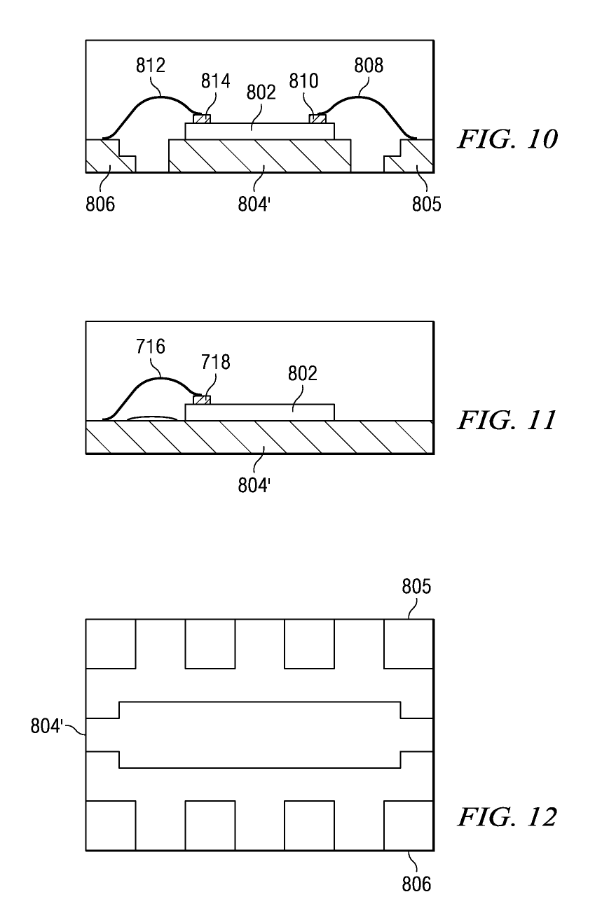

Referring to FIGS. 10 and 11, shown is an alternate embodiment of the package of FIGS. 8 and 9 with the die pad 804′ exposed to the bottom of the package.

1. A minimal pin package for a mixed signal integrated circuit for a mixed signal processor based integrated circuit, comprising:
a semiconductor chip having a plurality of bond pads disposed thereon;
a digital processor digitally interfaceable with at least one of said bond pads on said chip;
an analog circuit block interfaceable with at least one of said bond pads on said chip;
a die pad on which said chip is mounted;
N terminals interfaced to the exterior of the package, one of which is integral with said die pad; and
bond wires for interfacing select ones of said bond pads on said chip to a supply designated one of said terminals, a ground one of said terminals and said die pad associated with one of said terminals, the rest of the N-3 terminals interfaced to remaining functionality of said chip.

2. The package of claim 1, wherein the remaining of the N-3 terminals are associated with one of said bond pads that is interfaceable to either said processor or to said analog circuit block, and one of said terminals interfaced to a bond pad associated with timing functionality of said chip.

3. The package of claim 1, wherein the remaining of the N-3 terminals are interfaced to an oscillator disposed on said chip to allow a crystal to be interfaced thereto, with others of said N-3 terminals interfaced to said processor or said analog circuit block.

4. The package of claim 3, and further comprising a multiplexer disposed on said chip for being configured to selectively connect either the crystal input to said oscillator, the input to said analog circuit block or the digital interface to said processor, with the remaining of said N-3 terminals not associated with the timing input to said chip.

5. The package of claim 4, wherein said multiplexer is operable to selectively interface either an external crystal with said oscillator or to interface the input to said analog circuit block or digital interface to said processor with the ones of said pins that could be connected to said oscillator.

6. The package of claim 1, wherein said digital processor is an instruction based processor.

7. The package of claim 6, and further comprising a memory disposed on said integrated circuit and wherein the timing input to the one of said terminals associated therewith is utilized at least a portion of the time for allowing data to be transferred to said memory via the one of said data terminals for interfacing to said digital processor or said analog circuit block.
